(19) United States
(12) Patent Application Publication
(10) Pub. No.: US 2008/0250978 A1
(43) Pub. Date: Oct. 16, 2008

(54) Hydrophobic self-cleaning coating composition

(76) Inventors: Richard J. Baumgart, Paris, KY (US); Subbareddy Kanagasabapathy, Lexington, KY (US); Frances E. Lockwood, Georgetown, KY (US)

Correspondence Address: WOOD, HERRON & EVANS, LLP, 2700 CAREW TOWER, 441 VINE STREET, CINCINNATI, OH, 45202, US

(21) Appl. No.: 12/009,318

(22) Filed: Jan. 17, 2008

Related U.S. Application Data
(60) Provisional application No. 60/967,441, filed on Sep. 5, 2007.

(30) Foreign Application Priority Data
Apr. 13, 2007 (US) PCT/US07/09248

(51) Int. Cl. C23C 16/40; C08G 67/00; C23C 16/00; C08L 83/00; C09D 5/00; C23C 16/06

(52) U.S. Cl. 106/287.19; 524/612; 106/287.18; 106/287.24; 106/287.26; 106/287.23; 106/287.34; 524/543; 524/588

(57) ABSTRACT

The present invention provides a water based, low VOC super hydrophobic coating composition that can be used to make wet and dry dirt repellent surfaces to keep the surfaces clean for a reasonable period of time. The coating utilizes hydrophobic nanoparticles dispersed in water. This treatment produces a virtually transparent coating releasing very little or no VOC compounds whereas previous coatings of comparable hydrophobicity release up to 99 percent VOC compounds. The coating can be applied by a simple, single application method and the super hydrophobic property can be achieved by drying at room temperature for 5 to 10 minutes. A preferred coating can be easily removed and renewed when desired. The aqueous hydrophobic self cleaning coating composition that can be applied by conventional methods such as by spraying the composition onto a surface creating a wet and dry dirt repellent coating on the surface. The hydrophobic self cleaning coatings are used on exterior automotive and boat surfaces, and in many other applications, to produce a self cleaning surface, reduce adherence of dirt and contaminants to a treated surface, and reduce drag in some applications providing an energy savings. The coating solves the problem of poor resistance to UV light, opaque appearance, and/or abrasion found in previous coatings of similar nature. A preferred coating has good resistance to UV light and some resistance to abrasion. Clear, nearly transparent and translucent coatings are produced as compared to conventional coatings of comparable hydrophobicity which are typically white or opaque. The coating can be applied by a single and easy spraying method and the super hydrophobic property can be achieved by drying the film by evaporation of the solvent wetting solution and water based carrier at ambient temperature for 5 to 10 minutes. Embodiments of the hydrophobic self-cleaning coating composition can be produced resulting in a clear coating or in some cases a translucent dirt repellant film or coating on painted material, plastic, metal, glass, ceramic, fiberglass or a polymer substrate. The coating typically utilizes hydrophobic nanoparticles of fumed silica and/or titania wetted by a hydrophilic solvent such as acetone for no VOC applications, or with mineral spirits, alcohol or a light distillate if VOC are not a consideration, together with a selected surfactant typically having an HLB value in a range of from 9 to 13.

At least one preferred coating composition comprising an effective amount of a treated fumed silica wetted with a solvent and dispersed in water, upon drying, resulted in a coated surface providing a contact angle of at least 165 degrees and a surface energy below 12 dynes/centimeter as compared to water having a contact angle of from 65 to 80 degrees on a noncoated surface. The composition imparts a degree of hydrophobicity to a surface so that the surface will have a tilt angle of sliding of less than 2 degrees as compared to water on a noncoated surface having a tilt angle of sliding of 90 degrees or higher. The coating composition is removed by washing with a detergent or applying pressure to the coating wiping same from the treated surface. Exposure to water in the form of rain or snow does not remove the coating composition.

### RELATED APPLICATIONS

This application is a provisional application claiming priority from U.S. application Ser. No. U.S. application Ser. No. 11/699,883 filed on Jan. 30, 2007 claiming priority from Provisional Application Ser. No. 60/763,294 filed on Jan. 30, 2006 and U.S. Provisional Application Ser. No. 60/841,720 filed on Aug. 31, 2006 and claiming priority from U.S. patent application Ser. No. 11/787,214 and PCT/US07/09248 both of which were filed on Apr. 13, 2007 claiming priority from U.S. Provisional Application Ser. No. 60/791,853 filed on Apr. 13, 2006 all of which are incorporated by reference herein in their entirety. Reference to documents made in the specification is intended to result in such patents or literature cited are expressly incorporated herein by reference, including any patents or other literature references cited within such documents as if fully set forth in this specification.

### TECHNICAL FIELD

The technical field of this invention is related to producing water based super hydrophobic coatings on surfaces to produce self-cleaning surfaces.

### BACKGROUND OF THE INVENTION

This invention relates to appearance maintenance and enhancement, and protection of various surfaces from contaminants and from oxidation of surfaces in air and corrosion by moisture. One of the primary applications include the use of this technology in vehicle appearance products. Although, products for similar applications are widely available on the market, these products often require rinsing with water after use and usually rely on a temporary hydrophilic surface. Typically when the water dries from the surface, water marks, smears or spots are left behind due to the deposits of minerals which were present as dissolved solids in water. This problem is apparent when cleaning glass, painted surfaces, steel, alloy, plastic or ceramic surfaces. A means of solving this problem known in the literature is to dry the water from the surface using a cloth or chamois before the water marks form. However, this drying process is time consuming and requires considerable physical efforts.

The lotus plant exhibits self cleaning properties because the surface of the leaves are covered with small nano sized projections, bumps or ridges. Surfaces exhibiting super hydrophobic characteristics due to nano sized irregularities thereof are often referred to as exhibiting the “Lotus Effect”. Super hydrophobic coatings utilizing nano sized irregularities applied to a surface form a high contact angle which resist wetting and adherence of dirt and contaminants.

The only commercially available hygroscopic materials for producing this non-wetting and self-cleaning effect are fumed silica products sold under the trade name of MINCOR from BASF, and/or TEGOTOP from Degussa. Testing of the products have resulted in unsuitable coatings when for application to substrates when coated alone or mixed with various types of hydrophobic particles, these and many other polymers, for example: acrylic resins, silicon containing graft copolymers, functional/non functional siloxanes, inorganic hybrids such as silsesquioxanes, acrylic polymers containing perfluoro pendant groups, TEFLON/NAFION type fluoro polymers, urethanes, fluorourethanes, polyethers, polyesters and silicon modified polyacrylates. It was found that the resulting coating is initially super hydrophobic and may remain so for long periods indoors. However, when exposed to outdoor UV light, rubbed even slightly, or in general exposed to weather, the coating loses super hydrophobicity (which we define as the instant shedding of water with no remaining drops) and becomes less hydrophobic within days or even hydrophilic and hence less useful for the object of this invention.

Water has a contact angle of from 65 to 80 degrees and a tilt angle of sliding of 90 degrees or higher on a noncoated surface.

At least one pertinent references teach compositions producing a self cleaning coating having a surface energy of below 30 dynes per centimeter which will produce a material having a contact angle of around 100 degrees. Achieving a contact angle of about 150 degrees usually requires that the coating be applied to a surface having some nano roughness. The use of low surface energy functional groups such as perfluoro groups results in contact angle of around 120-130 degrees. At least one reference uses TiO₂ particles which are hydrophillic.

At least one preferred coating composition of the present invention comprises an effective amount of a treated fumed silica particles which are super hydrophobic wetted with a solvent and dispersed in water, upon drying, resulted in a coated surface providing a contact angle of at least 165 degrees and a surface energy below 12 dynes/centimeter. The composition of the present invention imparts a degree of hydrophobicity to a surface so that the surface will have a tilt angle of sliding of less than 2 degrees as compared to water on a noncoated surface having a tilt angle of sliding of 90 degrees or higher. The coating composition is removed by washing with a detergent or applying pressure to the coating wiping same from the treated surface. Exposure to water in the form of rain or snow does not remove the coating composition.

### DESCRIPTION OF THE PRIOR ART

This invention relates to protection of various surfaces from contaminants and from oxidation of surfaces in air and corrosion by moisture by producing a super hydrophobic coating with little or no VOC components. One of the primary applications includes the use of this technology in car appearance products such as wheel coatings and car body coatings including glass. Not only will this super hydrophobic coating keep the surface clean for several weeks, it will also keep water spots from forming. There are several published articles which address the elimination of water marks. In one example, U.S. Pat. No. 5,759,980, a composition, comprises a surfactant package consisting of a silicone-based surfactant and a polymer which is capable of bonding to a surface to make a hydrophilic film which eliminates the problem of water marks. However, this hydrophilic coating may tend to be removed from the surface by a single water rinse. DE-A21 61 591 also describes a composition for cleaning cars wherein the surface is again made hydrophilic by using amino functional polymers. This coating also tends to be rinsed off from a single rinse. In another work, PCT WO97/48927, a direct method of a cleaning composition, method of application and apparatus were described. This work describes using a spray gun comprising separate chambers for the cleaning solution and ion exchange resin. Moreover, it recommends to use purified rinse water which is expensive to use. There are a number of waxes and other products available in the market for attempting to retain this spot free finish. Typically these products are designed to hydrophobically modify the surfaces after waxing so that the water will bead up on the hydrophobic surface. However, the hydrophobicity of the surfaces are not sufficient to remove the water but only to bead the water thereby leaving the water spot when the water drops dry. Very recently, Degussa (US 2006/0110542) have reported a coating composition that is composed of fumed silica and an organic solvent to create a super hydrophobic film. However, this composition contains more than 98% of VOC solvents resulting in limited applications. Applicants are not aware of a superhydrophobic coating composition that contains very low or no VOC for use in the consumer market.

Therefore, there is a need to develop a low or no VOC containing composition process for protecting various surfaces from the appearance of water marks, corrosion and dirt while maintaining the water repellency even after several water rinses.

The present invention relates to a process for creating super hydrophobic coatings (contact angle>150 degree) and more preferably having a contact angle>165 degrees, on various surfaces, preferably plastics, metals, glass, ceramics, and painted surfaces using a water based with little or no VOC components. Super hydrophobic coatings containing high VOC solvents have recently been cited (Degussa US 2006/0110542) for the purpose of keeping surfaces cleaner, similar to the lotus plant, and the high contact angle is known as the “lotus effect”. However, the only materials so far commercialized to produce this cleaning effect, e.g. MINCOR from BASF, and or TEGOTOP from Degussa, have been tested by us and have been found to be unsuitable when coated alone or mixed with various types of hydrophobic particles, These and many other polymers, for example, acrylic resins, silicon containing graft copolymers. functional/nonfunctional siloxanes, inorganic hybrids such as silsesquioxanes, acrylic polymers containing perfluoro pendant groups, TEFLON/NAFION type fluoro polymers, urethanes, fluorourethanes, polyethers, polyesters and silicon modified polyacrylates, produce a coating which is initially super hydrophobic and may remain super hydrophobic for long periods indoors. However, when exposed to outdoor UV light, rubbed even slightly, or in general exposed to weather, the coating loses super hydrophobicity (which we define as the instant shedding of water with no remaining drops) and becomes less hydrophobic within days or even hydrophilic and hence less useful for the object of this invention. These conventional prior art coating materials all contain up to 95 percent VOC compounds. Examination under the microscope after a week of exposure on a panel in a UV cabinet reveals that a coating made from fumed silica and at least one film forming binder as per U.S. Pat. No. 6,683,126 disintegrates. Furthermore it has been published that lotus type coatings, when exposed to steam, lose their hydrophobicity. We have found that the state of the art is that no practical lotus coatings exist for the object of this invention that involves environmentally friendly water based formulations.

The invention described herein provides a process for long lasting super hydrophobic coatings that have the benefit of self cleaning of various surfaces and will reduce icing caused by water drops using a composition containing very low or no VOC compounds. Furthermore, the invented coatings are inexpensive compared to paint and can be applied regularly if necessary to keep the surface clean without any further steps.

Moreover, self cleaning film forming coatings known in the art are primarily for solvent based compositions. Additional examples of solvent based systems are as follows:

Examination under the microscope after a week of exposure on a panel in a UV cabinet reveals that a coating made from fumed silica and at least one film forming binder as per U.S. Pat. No. 6,683,126 by Keller et al. issued in Jan. 27, 2004 is disintegrates where the polymers were selected from the class that have hydrophobicity such that the contact angle of the binders were above 90 degrees. (U.S. Pat. No. 6,683,126). Furthermore it has been published (GM reference) that lotus type coatings, when exposed to steam, lose their hydrophobicity. We have found that the state of the art is that no practical self cleaning water based coatings exist for the object of this invention.

There are several published articles which address the elimination of water marks. In one example, U.S. Pat. No. 5,759,980, a composition, comprises a surfactant package consisting of a silicone-based surfactant and a polymer which is capable of bonding to a surface to make a hydrophilic film which eliminates the problem of water marks. However, this hydrophilic coating may tend to be removed from the surface by a single water rinse. German publication DE-A21 61 591 also describes a composition for cleaning cars wherein the surface is again made hydrophilic by using amino functional polymers. This coating also tends to be rinsed off from a single rinse.

U.S. Pat. No. 7,196,043 by Valpey, III, et al. teaches a process and composition for producing self-cleaning surfaces from aqueous systems; however, experiments conducted using the method taught by Valpey did not result in confirmation of the water contact angle with respect to surface modifier: The patent teaches that for most of the surface modifiers the maximum contact angle achieved was 120 degrees. One specific surface modifier shown in example 2e shows the contact angle was above 140 degree. A laboratory experiment was conducted to reproduce example 2e to attain 150 degree contact angle. Duplication of the experimental method taught in the patent example procedure however, did not result in duplication of the data and a contact angle of 150 degrees was not obtainable as reported in the patent. It's obvious from the literature and also from our observations that by using low surface energy functional group such as perfluoro groups, the contact angle is going to be around 120-130 degree. The surface has to be made to the scale of nano roughness in order to achieve contact angle higher than 130 degree. Therefore by repeating the example 2e, the contact angle can not reach 150 degrees. Furthermore, claim 1 claims that the surface energy of the coating is below 30 dynes per centimeter but did not define the exact amount of surface energy. The contact angle for a material with the surface energy 30 dynes/cm will be around 100 degrees. With this surface energy, it is nearly impossible to attain the contact angle 150 degree unless the surface has some nano roughness. Finally the reference teaches the use of used TiO2 particle which is hydrophilic as the substrate.

U.S. Pat. No. 6,660,363 by Barthlott granted on Dec. 9, 2003 teaches a means for permanently bonding hydrophobic polymers forming elevations and depressions between 5 to 200 nanometers creating a hydrophobic surface. U.S. Pat. No. 3,354,022 teaches that a permanent water repellant surface having a contact angle of more than 90 degrees can be formed from a polymer upon forming high and low projections having a high and low range of 1,000 microns or less. U.S. Patent Application S.N. 2005/0136217 A1 published on Jun. 23, 2005 by Barthlott et al. teaches a coating producing protrusions and recesses in a ratio having a distance range of from 0.1 to 200 m and the height in a range of from 0.1 to 100 m.

U.S. Pat. Pub. No. 2004/0213904 describes a process for producing detachable dirt- and water-repellent surface coatings on articles. Hydrophobic particles are applied to the surface of the articles generating elevations on the surface of the articles that has dirt- and water-repellent properties. The process suspends the hydrophobic particles in a solution of an alkyl-modified silicone wax in a highly volatile siloxane. The suspension is applied to a surface of an article. The highly volatile siloxane is removed forming a coating. A disadvantage is that the coating appears to have a grayish or hazy layer.

In another example, PCT WO97/48927 teaches a direct method of a cleaning composition, method of application and apparatus. This reference describes using a spray gun comprising separate chambers for the cleaning solution and ion exchange resin. Moreover, it recommends to use purified rinse water which is expensive to use. There are number of waxes and other products available in the market for attempting to retain this spot free finish. Typically these products are designed to hydrophobically modify the surfaces after waxing so that the water will bead up on the hydrophobic surface. However, the hydrophobicity of the surfaces is not sufficient enough to bead the water completely from the surface thereby leaving the water spot when the water dries. Moreover, the prior art relating to hydrophobic and/or self-cleaning coatings is primarily related to permanent attachment to the substrate being coated rather than being a temporary and replenish able coating.

U.S. Patent publication 20060110542 published on May 25, 2006 discloses a composition for forming a detachable and renewable protective coating produced by making a highly concentrated dispersion of hydrophobically modified silica particles in the presence of a disilazane derivative under high shear conditions. Thus, a binder is required for the composition.

Although a variety of polymers will work if coated with a hydrophobic nanoparticles material, e.g. silsesquioxanes, perfluoroacrylic resins etc. only a few polymers serve as an adequate base for the particles because the surface area of exposed polymer is vastly increased due to very thin film and rough surface area produced by the coating. This problem was either not understood or not solved in the prior art references.

Therefore, there is a need to develop a water based process and coating for protecting various surfaces from the appearance of water marks, corrosion, and dirt repellency, while maintaining the water repellency even after several water rinses, which is clear or at least nearly transparent and removable with conventional detergents.

### SUMMARY OF THE INVENTION

The object of this invention is to provide a low or no VOC super hydrophobic coating, which is so hydrophobic that water will bounce off the surface of nominally horizontal coated surfaces. In this case the contact angle is so large (greater than 165 degree) that it can not be measured by conventional instrumentation. Other objects of this invention are to provide superhydrophobic coatings that are: I) practical to use, ii) do not degrade rapidly in sunlight, iii) can be readily applied, and iv) have enough resistance to abrasion to survive for a practical length of time, for at least one month and up to years, even with environmental exposure in the application of use. Another object is to provide a process for applying such coatings using a single application (one coating, not two or more).

The instant invention is a composition having a small amount of hydrophobic particles dispersed in water that have good adhesion to metals, glass, plastic, painted and many other surfaces. This composition does not comprise any binding materials as reported as an essential part of compositions used in other literature methods. The nanoparticles can be applied in a broad range of solid mixtures. The final uniform coating can be obtained by drying the film at room temperature for 5 to 10 minutes.

The present invention provides a coating composition which is super hydrophobic, and when applied on a surface, typically metal, fiberglass, plastic, ceramic, glass, painted material, etc. produces a difficult to wet surface. Contact angles of a liquid such as water on the coated surface should be difficult to measure with conventional means because the water droplet bounces or runs off the surface when applied. The contact angle exceeds 165 degrees and the tilt angle of sliding is less than 2 degrees.

The static contact angle of a drop of liquid can be used to measure the wet ability of surfaces. The static contact angle, (“contact angle”), can be defined as the angle enclosed by the surface and a tangent along the surface of the liquid drop in the region of the contact point of the liquid drop with the surface. The contact angle is measured through the liquid drop. A contact angle of 0 defines complete wettability and does not form a drop. A contact angle of 180 degrees defines complete unwettability.

The surface energy for a preferred embodiment of a coating as set forth in Example 1 is below 12 dynes/cm. This combined with creating the roughness to the surface brings the contact angle above 160 degree in our coatings. Some patents used TiO2 particles which ares hydrophilic where as we have use treated SiO2 particles that are superhydrophobic.

The coatings of this invention are produced by hydrophobic particles dispersed in water with little or no VOC compounds. Contact angles of water on the coated surface should be difficult or impossible to measure with conventional means because the water droplet bounces or runs off the surface when applied. The contact angle exceeds 165 degrees and the tilt angle of sliding is less than 2 degrees.

The water dispersed coatings are optimized formulations that contain super hydrophobic nanoparticles, for example, treated fumed silica. Although a variety of nanoparticles will work if coated with a hydrophobic material, e.g. silsesquioxanes, perfluoroacrylic resins etc. only few polymers serve as an adequate base for the particles because the surface area of exposed polymer is vastly increased due to very thin film and rough surface area produced by the coating. UV stability of the super hydrophobic coatings is extremely important especially for exterior surfaces which are exposed to UV light. For example, in U.S. Pat. No. 6,683,126 the authors state that “the nature of the binder . . . is of fairly minor importance for the success of the invention, provided the binder is sufficiently hydrophobic”. Our finding is that the careful selection of the nanoparticle in the composition without any binder will produce a practical lotus effect that is not easily destroyed by fog, UV light, or abrasion, e.g. by heavy rain or wind, thus the patent teaches away from formulation of a super hydrophobic coating without a binder.

This transparent, more uniform film is stable when exposed outdoors to strong UV light, rain, wind, etc. for a minimum time of one month, compared to 3 days for most other polymers including acrylates, urethane acrylates, homopolymers and copolymers of ethylenically unsaturated monomers, acrylic acid/maleic anhydride copolymers etc. Stability is determined by observing that the super hydrophobic effect has not diminished and by examining the film under the microscope before and after exposure.

Nanoparticles that can be used to make the coatings of this invention are generally from the class of fumed silica's and/or zinc oxides, e.g. Degussa AEROSIL R8200, Degussa AEROSIL R812 S, CAB-O-SIL TS 530, TS 610, TS 720.

In order to disperse treated, hydrophobic silica or other hydrophobic particles into water, the hydrophobic particles must be wetted by a non-aqueous liquid such as ketone, glycol ethers, alcohols, aliphatic hydrocarbon solvents, polydimethylsiloxane, cyclic polydimethylsiloxane, aromatic hydrocarbon solvents, tetrahydrofuran, acetic acid, acetates, glycols. A non VOC material may be selected or a VOC exempt material may be selected to produce a non VOC hydrophobic particle dispersion in water. Surfactants may also be used to help wet the metal surface in order to form a uniform super hydrophobic coating. Surfactants can be nonionic, cationic or anionic in nature.

The present invention relates to a process and composition for creating super hydrophobic coatings (contact angle>165 degree) on various surfaces, preferably plastics, metals, glass, fiberglass, ceramics, wood, and painted and/or waxed surfaces. Super hydrophobic coatings of this type have recently been cited for the purpose of keeping surfaces cleaner, similar to the lotus plant, and the high contact angle is known as the “lotus effect” which depends upon having a hydrophobic surface formed of wax with an irregular surface texture caused by nanometer sized projections or irregularities whereby the surface area of a drop of liquid such as water is not great enough to overcome the high contact angle formed with the hydrophobic surface resulting in the liquid being repelled from the surface. Examples of commercially available materials which attempt to produce this “Lotus” cleaning effect are products sold under the trade name of MINCOR available from BASF AG Corp., and TEGTOP available from Degussa. These products have been tested for their ability to protect various surfaces from the appearance of water marks, corrosion, and dirt repellency and while maintaining the water repellency, but were deemed unsuitable. When coated alone or mixed with various types of hydrophobic particles, these and many other polymers, e.g. acrylic resins, silicon containing graft copolymers, functional/non functional siloxanes, inorganic hybrids such as silsesquioxanes, acrylic polymers containing perfluoro pendant groups, polytetrafluoroethylene, NAFION type fluoro polymers, urethanes, fluorourethanes, polyethers, polyesters and silicon modified polyacrylates, it was found that the resulting coating is initially super hydrophobic and may remain so for long periods indoors; however, when exposed to outdoor UV light, rubbed even slightly, or in general exposed to weather, the coating loses super hydrophobicity (which we define as the instant shedding of water with no remaining drops) and becomes less hydrophobic within days or even hydrophilic and hence less useful for the object of the present invention. Examination under the microscope after a week of exposure on a panel in a UV cabinet reveals that a coating made from fumed silica and at least one film forming binder as taught in U.S. Pat. No. 6,683,126 disintegrates. None of the conventional hydrophobic compositions known provide a long lasting super hydrophobic coating that has the benefit of self cleaning of various surfaces and will reduce icing caused by water drops, is removable with detergents, and clear or nearly transparent. Moreover, snow and ice covering horizontal surfaces can be more easily removed from the surfaces protected with the coating formed from the composition of the present invention. The coatings of the instant invention are inexpensive compared to paint and can be sprayed regularly if necessary to keep the surface clean without any further steps.

In the instant invention polymer resins with UV light stability and good adhesion to metals, glass, plastic, painted and many other surfaces, are combined with hydrophobic binders such as silicone or fluorine containing polymers etc. Organic polymers or inorganic polymers or a combination thereof are blended with a small amount of hydrophobic nanoparticles of fumed silica and/or titania and/or zinc oxide in a solvent so that the coating imparts sufficient surface roughness for super hydrophobicity. The polymer and nanoparticles can be applied by brush, dipping, or spraying in a broad range of solid mixtures using VOC complaint solvents and can be applied using an aerosol propellent. The final uniform coating can be obtained by drying the film at room temperature for 5 to 10 minutes.

The present invention described herein provides a long lasting transparent, removable self cleaning super hydrophobic coating that has the benefit of reducing drag, noise, and will reduce icing caused by water drops. However it should be noted that snow will cover horizontal surfaces but can be more easily removed from the surfaces protected with the invented coatings. Furthermore, the invented coatings are inexpensive compared to paint and can be sprayed regularly if necessary to help prevent icing.

The hydrophobic self-cleaning properties of the coating composition of the present invention forms an almost clear, transparent dirt repellant film or coating on painted material, plastic, metal, glass, ceramic, fiberglass or polymer substrate. A preferred coating composition comprising an effective amount of a treated fumed silica wetted with a selected solvent, dispersed in water and applied to a surface resulted in a coated surface providing a contact angle of at least 165 degrees as compared to water having a contact angle of from 65 to 80 degrees on a noncoated surface. The composition also imparted a degree of hydrophobicity to the treated surface resulting in a tilt angle of sliding of less than 2 degrees as compared to water on a noncoated surface having a tilt angle of sliding of 90 degrees or higher.

In the instant invention, compositions are provided having a small amount of nanoparticles of fumed silica and/or titania, or other hydrophobic nanoparticles component with good UV light stability and good adhesion to metals, glass, plastic, painted and many other surfaces. The composition does not require any binding materials as taught in the prior art.

The coating composition of the present invention can be conveniently applied as an aerosol. If propellant is used it will generally be in an amount from about 10 wt % to about 100 wt % of the aerosol formulation. Normally, the amount of a particular propellant should provide an internal pressure of from about 40 to 100 p.s.i.g. at 70° F. The suspended treated silica generally will be in an amount from about 0.1 wt % to about 10 wt % of the aerosol formulation. To make the silica coating easier to apply it can be wetted with a solvent prior to being dispersed in the water carrier. The composition of the solvent wetting agent can be in the range of 0.001 wt % to 20 wt %.

The object of this invention is to provide a super hydrophobic coating, that is so hydrophobic that water will bounce of the surface of nominally horizontal coated surfaces. In this case the contact angle is so large, (greater than 165 degrees in at least one embodiment), that it cannot be measured by conventional instrumentation.

The present invention relates to a process and composition for creating hydrophobic coating compositions having a contact angle of 165 degrees or greater on various surfaces, preferably plastics, metals, glass, ceramics, and painted and/or waxed surfaces.

The present invention provides a coating composition and process for generating transparent, near-transparent, and translucent super-hydrophobic coatings on surfaces having a contact angle of greater than 165 degrees.

The super hydrophobic coating composition that can be used to make wet and dry dirt repellent surfaces to keep the surfaces clean for a reasonable period of time.

The coating solves the problem of poor resistance to UV light and/or abrasion found in previous coatings of similar nature. The transparent, near transparent, or translucent coatings can be produced using the current invention whereas previous coatings of comparable hydrophobicity have all been white or opaque.

The present invention relates to at least one embodiment of a process and a composition for creating hydrophobic self cleaning coatings having a contact angle of at least 165 degrees on various surfaces, preferably plastics, metals, glass, ceramics, and painted and/or waxed surfaces.

It is an object of the present invention to provide a formulation of a hydrophobic coating which resists abrasion and the elements particularly ultraviolet “UV” light. UV light stability of the super hydrophobic coatings is extremely important especially for exterior surfaces such as on automobiles and other vehicles used for transportation and recreation.

It is another object to provide a self-cleaning coating for application to transparent or translucent glass, plastic, or metal panels for use in building and automotive windows.

It is another object to provide a self-cleaning coating for application to glass, plastic, or opaque metal panels for use in building and automotive windows.

It is another object to provide a self-cleaning coating for application to glass, plastic, or metal panels to reduce the static cling of dust particles.

It is another object to provide a self-cleaning coating to the interior or exterior of metal tanks such as aluminum or stainless steel used for storage or transport of liquids by truck, railcar, airplane, or ship.

Another object is to provide coatings that are practical in use, that do not degrade rapidly in sunlight, that can be readily applied, and have enough resistance to abrasion to survive for a practical length of time depending upon the application for a significant amount of time to decrease the adhesion of dirt on a coated surface subjected to gas, liquid, and solid fluid flows and/or combinations thereof as compared to uncoated surfaces even with environmental exposure in the application of use.

Another object is to provide a process for applying a self cleaning coating containing hydrophobic nanoparticles without the use of adhesives or by pre-treating the surface of the substrate to be coated with an adhesive.

It is another object of the present invention to provide a self cleaning coating composition containing hydrophobic nanoparticles that cures by evaporation of the volatile solvent and/or water carrier and does not require any special treatment such as heat, IR or UV light, or crosslinking to cure.

It is an object of the present invention to provide a hydrophobic self-cleaning composition which upon application to a surface forms a uniform coating by drying and evaporation of the water based carrier forming a coating or film at ambient temperature within 5 to 10 minutes.

The hydrophobic coating composition forms an almost clear, translucent film or coating on painted material, plastic, metal, glass, ceramic, fiberglass or polymer substrate. A preferred coating composition comprising an effective amount of a treated fumed silica wetted in a solvent and dispersed in water upon curing by evaporation will result in a coated surface providing a contact angle of at least 165 degrees as compared to water having a contact angle of from 10 to 15 degrees on a noncoated surface. Said composition imparts a degree of hydrophobicity to a surface so that the surface will have a tilt angle of sliding of less than 2 degrees as compared to water on a noncoated surface having a tilt angle of sliding of 90 degrees or higher.

It is an object of the present invention to provide a super hydrophobic coating, which is so hydrophobic that water will bounce off the surface of nominally horizontal coated surfaces. In this case the contact angle is so large (greater than 165 degrees) that it can not be measured by conventional instrumentation.

Another object of the present invention is to provide coatings that are practical in use, that do not degrade rapidly in sunlight, that can be readily applied, and have enough resistance to abrasion to survive for a practical length of time, preferably for weeks or months depending upon environmental conditions to which the coating is exposed.

It is an object of the present invention to apply the hydrophobic nanoparticles containing composition by conventional methods of application such as by spraying, brushing, or dipping.

It is an object of the present invention to provide a hydrophobic self cleaning composition which upon application to a surface forms a uniform coating by drying and evaporation of the solvent wetting agent and water based carrier forming a coating or film at ambient temperature within 5 to 10 minutes.

Accordingly, it is an object of the present invention to provide a clear, translucent, pigmented, florescent, dyed, tinted, or illuminative hydrophobic self cleaning coating for application to a metal, plastic, glass, cloth, ceramic, clay, fiber, concrete, brick, rock, cinder block, paper, film, or wood surface.

It is an object of the present invention to be applicable in a pressurized container, tube, aerosol, or spray bottle or applied by pump spray, brush, roll, or dipping onto dry surfaces.

It is an object of the present invention to provide a self cleaning coating which can be easily removed after being placed on a solid substrate such as paints, metals, plastics, concrete, natural and synthetic elastomers, and ceramics and removed by washing with detergent, mechanical means such as brushing or applying pressure to the coating by high pressure sprays.

It is an object of the present invention to provide a water based carrier for the self cleaning hydrophobic coating for use on metal, plastic, glass, paper, or wood surfaces having existing protective coatings of paint, varnish, film, without damaging the existing protective coatings.

It is another object of the present invention to produce a removable coating which does not damage the surface.

It is yet another object of the present invention to produce a protective coating which will not damage paint, chrome, plastic, fiberglass, or other substrate to be coated therewith.

It is another object of the present invention to produce a self cleaning hydrophobic coating which is easily to apply as a liquid, foam, jell, paste, semi-solid, or aerosol.

It is another object of the hydrophobic coating embodiment to be applied to surfaces without complicated apparatus.

It is yet another object of the hydrophobic coating to cure by evaporation of a selected volatile solvent wetting agent and water based carrier at ambient temperature thereby drying and forming a thin film, and not requiring a cross-linking curing agent.

A preferred composition utilizes a fumed silica compound such as a hydrophobic fumed silica in an amount of up to 10 percent by weight based on the total weight of the composition. Optionally an effective amount of a fragrance can be added to the formulation. In addition, an effective amount of a propellant can be added to the formulation. Other optional components which may be added to the composition which are not required, but impart desirable qualities to the composition include a colorant such as a dye or pigment in an effective amount of about 0.005 percent by weight of the total composition; a fragrance such as bubblegum in an effective amount of about 0.10 percent by weight of the total composition; and/or a preservative such as SURCIDE P in an effective amount of about 0.1 percent by weight of the total composition.

It is an object of the present invention to provide a super hydrophobic self-cleaning nanoparticles containing composition which can be sprayed in a broad range of solid mixtures using VOC complaint solvents for wetting the hydrophobic particles with or without aerosol propellants. For instance, a pressurized liquid propellant may be utilized as a carrier to apply the foamed film coating. The preferred embodiments of the present invention use a nonfloronated propellant. A commercial liquid hydrocarbon propellant which is compatible with the preferred composition may be selected from the group of A-31, A-46, A-70, or A-108 propane/isobutane blends, with A-46 and A-70 being the most preferred propellant for use with particular compositions. Other propellants that can be used are CO2, nitrogen, or air. The composition may contain up to 25 weight percent of the propellant, and more preferably from 5 to 20 weight percent of the selected propellant.

Accordingly, it is an object of the present invention to provide a clear, translucent, pigmented, florescent, dyed, tinted, or illuminative hydrophobic self-cleaning coating for application to a metal, plastic, glass, cloth, ceramic, clay, fiber, concrete, brick, rock, cinder block, paper, film, or wood surface.

It is an object of the present invention to provide a self-cleaning coating which can be easily removed after being placed on a solid substrate such as paints, metals, plastics, concrete, natural and synthetic elastomers, and ceramics and removed by washing or applying pressure to the coating wiping same from the treated surface.

It is an object of the present invention to provide a water based carrier for the self-cleaning hydrophobic coating for use on metal, plastic, glass, paper, chrome, surfaces having existing protective coatings of paint, varnish, and film, without damaging the existing protective coatings.

It is another object of the present invention to produce a self cleaning hydrophobic coating which is easily to apply as a liquid, foam, jell, paste, semi-solid, or aerosol.

It is another object of the self cleaning hydrophobic coating embodiment to be applied to surfaces without complicated apparatus.

It is yet another object of the self-cleaning hydrophobic coating to cure by evaporation of a selected wetting solvent and water based carrier at ambient temperature and not requiring a cross-linking curing agent.

It is an object of the present invention to provide a self-cleaning hydrophobic coating which can be applied by brush, roll, spray, or dipping onto dry surfaces.

It is an object of the present invention to be used for treating non-porous and porous surfaces such as automotive and household materials including wheels, wheel trim, wheel covers, removable wheel covers, splash guards, car panels and painted surfaces, clear-coated car surfaces, metal, painted metal fixtures, chromed articles, bumpers, bumper stickers, bug deflectors, rain deflectors, vinyl materials including car boots, wheel covers, convertible tops, camper awnings, sun shades, vehicle covers, license plates, plastic articles, lens covers, signal light lens covering, brake light lens covering, headlamp and fog light lens, vinyl, rubber, plastic, and leather surfaces, dashboard, dash instrument lens covering, seats, carpet, and floor runners.

It is an object of the present invention to be used for treating metals, metal oxides, aluminum, anodized aluminum, painted substrates, stainless steel, chrome, clear-coated automotive surfaces, elastomers, vinyl, plastics, polymers, sealed wood, laminates, composites, and the like.

It is an object of the present invention to be used for treating carpet, curtains, marble, granite, stone, brick, concrete, grout, mortar, drywall, spackling, plaster, adobe, stucco, unglazed tile, tile, unglazed porcelain, porcelain, clay, wallpaper, cardboard, paper, wood, and the like.

The foregoing objects are accomplished by selecting hydrophobic nanoparticles which enables the formulation of a composition which will produce a practical self cleaning coating that is not easily destroyed by fog, UV light, abrasion, or by flowing water.

Other objects, features, and advantages of the invention will be apparent with the following detailed description.

### DESCRIPTION OF THE PREFERRED EMBODIMENT

The coatings in the examples are optimized formulations that contain super hydrophobic nanoparticles, for example, fumed silica and/or titania. Although a variety of nanoparticles will work if treated with a hydrophobic material, e.g. silsesquioxanes, perfluoroacrylic resins etc. only few polymers serve as an adequate base for the particles because the surface area of exposed polymer is vastly increased due to very thin film and rough surface area produced by the coating.

The present invention provides a formulation which can utilize nanoparticles in the composition without any binder to produce a practical lotus effect that is not easily destroyed by fog, UV light, or abrasion, or by flowing water.

Nanoparticles that can be used to make the coatings of this invention are generally derived from the class of fumed silica's and hydrophobic titania's and zinc oxides, e.g. DEGUSSA AEROSIL R8200, DEGUSSA AEROSIL 812 S, and CAB-O-SIL TS 530, TS 610, TS 720. The particle size of the nanoparticles are from about 7 to 200 nm and more preferably from about 10-100 nanometers.

Amounts listed in percentage are in weight percent as indicated as “wt. %”, (based on 100 wt. % active) of the total composition or formulation described. As used herein, the term “particle” is intended to include any discrete particle, primary particle, aggregate and/or aggregated collection of primary particles, agglomerate and/or agglomerated collection of aggregates, and/or colloidally dispersed particles, aggregates, agglomerates and/or loose assemblies of particulate materials, and combinations thereof.

To make the silica coating easier to apply it can be wet by one or more solvents, preferably acetone and or aliphatic hydrocarbons and/or other VOC complaint solvents prior to dispersion in water to make it coatable. The wetting agent solvent may also be selected from the groups consisting of a glycol, an alcohol, a hydrocarbon, mineral spirits/or and other light hydrocarbons.

A preferred method of application is by spraying the solvent/particle dispersion as an aerosol. Suitable propellants are carbon dioxide, a hydrocarbon (for example mixtures of propane, butane and isobutane), a fluorocarbon, difluoroethane, or compressed air. One preferred hydrocarbon is a propane/isobutane.

A more detailed description of some of the ingredients utilized in the preferred embodiments of the self cleaning hydrophobic compositions are as follows:

### Binders

The coating composition of the instance invention comprises a hydrophobic fumed particles wetted with a solvent and dispersed in a water based carrier. Although not a requirement a binder can be added as an option to the present composition and dispersed among the particles prior to wetting.

Although a variety of polymers will work if coated with a hydrophobic nanoparticles material, e.g. silsesquioxanes, perfluoroacrylic resins etc. only a few polymers serve as an adequate base for the particles because the surface area of exposed polymer is vastly increased due to very thin film and rough surface area produced by the coating. This problem was either not understood or not solved in the prior art references. Formulation of the coating to resist abrasion and the elements, particularly UV light is an object of this invention. UV stability of the super hydrophobic coatings is extremely important especially for exterior surfaces which are exposed to UV light.

The majority of the potential binders are not stable in the lotus type coating and only careful selection of the binder and/or formulation with stabilizing additives will produce a practical lotus effect that is not easily destroyed by fog, UV light, or abrasion, e.g. by flowing water. Furthermore the polymers must be selected from the class that have hydrophobicity such that the contact angle of water on the polymer surface alone exceeds 120 degrees.

A preferred class of UV stable hydrophobic polymers are the trimethylsilyl end capped siloxanes, e.g. Wacker Polymer NA. These polymers can be combined with 0.1 to 5% of hydrophobic fumed silicas such as DeGussa Aerosil R8200 and coated as diluted in 95% solvent, preferably acetone, to form a super hydrophobic coating. This coating is essentially a transparent, more uniform film that is stable when exposed outdoors to strong UV light, rain, wind, etc. for a minimum time of one month, compared to 3 days for most other polymers including acrylates, urethane acrylates, homopolymers and copolymers of ethylenically unsaturated monomers, acrylic acid/maleic anhydride copolymers etc.

A preferred embodiment of the present invention contains a binder in an effective amount of up to 2.0 percent by weight of the total composition. The more preferred embodiments of the invention utilizes an effective amount of ranging from 0.001 to 2.0 percent by weight, and more preferably in a range of from to 0.001 to 1.5 percent by weight, more preferably in a range of from to 0.01 to 1.5 percent by weight, more preferably in a range of from between 0.1 to 1.0 percent by weight, and more preferably between 0.1 to 0.5 percent by weight based on the total weight of the composition. One preferred embodiment as set forth in Example 4, uses a binder polymer (aminofunctional siloxanes from Dow Corning) in an amount of about 0.3 percent by weight based on the total weight of the composition.

### Hydrophobic Surface Modifier

The coatings in the examples are optimized formulations that contain super hydrophobic nanoparticles. Although a variety of nanoparticles will work if coated with a hydrophobic material, e.g. fumed silica and/or titania, perfluoroacrylic resins etc. only few polymers serve as an adequate base for the particles because the surface area of exposed polymer is vastly increased due to very thin film and rough surface area produced by the coating.

It is believed the instant composition is a novel combination of synergistic components even without the addition of a hydrophobic fumed silica; however, a preferred embodiment of the present invention contains hydrophobic fumed silica having a median particle size in the range between 100 and 4,000 nanometers, more preferably in a range of from 100 to 3,000 nanometers, and more preferably in a range of from 100 to 1,000 nanometers in an effective amount of up to 5 percent by weight of the total composition as applied to the substrate in order to form a transparent or nearly transparent film coating. Amounts in excess of 5.0 percent by weight can be used; however, the resulting dried coating will not be transparent, but will appear hazy. The more preferred embodiments of the invention utilizes an effective amount of less than 5.0 percent by weight, and more preferably ranging from 0.001 to 5.0 percent by weight, and more preferably in a range of from to 0.01 to 4.5 percent by weight and more preferably in a range of from to 0.01 to 3.0 percent by weight, and more preferably in a range of from between 0.1 to 2.0 percent by weight, and more preferably between 0.1 to 0.5 percent by weight based on the total weight of the composition. One preferred embodiment as set forth in Example 1, uses nanoparticles of modified silica particles in an amount of about 0.25 percent by weight based on the total weight of the composition.

Suitable modified fumed silica particles that may be used in the present invention include silica particles that have been hydrophobicized by any means known in the art.

Nanoparticles that can be used to make the coatings of this invention are generally from the class of fumed silicas and hydrophobic titanias and zinc oxides, e.g. Degussa AEROSIL R8200, Degussa AEROSIL812 S, Cab-o-sil TS 530, TS 610, TS 720. The composition of the present invention contains a hydrophobic fumed silica such as sold under the trade name of AEROXIDE LE3 to generate self cleaning nanostructured hydrophobic surfaces which repel water. The average particle size distribution of particles is believed to be between 100 to 4,000 nanometers. The LE 3 brand has a specific surface area (BET) of 100+−30 m₂g, a carbon content of 3 to 6 weight percent, tapped density of approximately 60 g/l (According to (DIN EN ISO 787/11, August 1983), and a moisture of less than or equal to 1.0 weight percent (2 hours at 105° C.).

Several types of modified fumed silica is set forth in U.S. Patent Publication No. US 2006/0110542 by Dietz et al. Published on May 25, 2006 which is incorporated by reference herein and are described as follows:

Colloidal silicon dioxide made from fumed silica prepared by a suitable process to reduce the particle size and modify the surface properties. The surface properties are modified to produce fumed silica by production of the silica material under conditions of a vapor-phase hydrolysis at an elevated temperature with a surface modifying silicon compound, such as silicon dimethyl bichloride. Such products are commercially available from a number of sources, including Cabot Corporation, Tuscola, Ill. (under the trade name CAB-O-SIL) and Degussa, Inc., Piscataway, N.J. (under the trade name AEROSIL).

Suitable modified fumed silica particles include, but are not limited to those commercially available from Degussa Corporation, Parsippany, N.J., as designated under the R Series of the AEROSIL[R] and AEROXIDE[R]LE trade names. The different AEROSIL[R]R and AEROXIDE[R]LE types differ in the kind of hydrophobic coating, the BET surface area, the average primary particle size and the carbon content. The hydrophobic properties are a result of a suitable hydrophobizing treatment, e.g., treatment with at least one compound from the group of the organosilanes, alkylsilanes, the fluorinated silanes, and/or the disilazanes. Commercially available examples include AEROSIL[R]R 202, AEROSIL[R]R 805, AEROSIL[R] R 812, AEROSIL[R]R 812 S, AEROSIL[R] R 972, AEROSIL[R]R 974, AEROSIL[R]R 8200, AEROXIDE [R] LE-1 and AEROXIDE [R] LE-2.

Other silica materials are also suitable when hydrophobically modified by use of hydrophobizing materials capable of rendering the surfaces of the silica particles suitably hydrophobic. The suitable hydrophobizing materials include all those common in the art that are compatible for use with the silica materials to render their surfaces suitably hydrophobic. Suitable examples, include, but are not limited to: the organosilanes, alkylsilanes, the fluorinated silanes, and/or the disilazanes. Suitable organosilanes include, but are not limited to: alkylchlorosilanes; alkoxysilanes, e.g., methyltrimethoxysilane, methyltriethoxysilane, ethyltrimethoxysilane, ethyltriethoxysilane, n-propyltrimethoxysilane, n-propyltriethoxysilane, i-propyltrimethoxysilane, i-propyltriethoxysilane, butyltrimethoxysilane, butyltriethoxysilane, hexyltrimethoxysilane, octyltrimethoxysilane, 3-mercaptopropyltrimethoxysilane, n-octyltriethoxysilane, phenyltriethoxysilane, polytriethoxysilane; trialkoxyarylsilanes; isooctyltrimethoxy-silane; N-(3-triethoxysilylpropyl)methoxyethoxyethoxy ethyl carbamate; N-(3-triethoxysilylpropyl)methoxyethoxyethoxyethyl carbamate; polydialkylsiloxanes including, e.g., polydimethylsiloxane; arylsilanes including, e.g., substituted and unsubstituted arylsilanes; alkylsilanes including, e.g., substituted and unsubstituted alkyl silanes including, e.g., methoxy and hydroxy substituted alkyl silanes; and combinations thereof. Some suitable alkylchlorosilanes include, for example, methyltrichlorosilane, dimethyldichlorosilane, trimethylchlorosi lane, octylmethyldichlorosi lane, octyltrichlorosilane, octadecylmethyldichlorosilane and octadecyltrichlorosilane. Other suitable materials include, for example, methylmethoxysilanes such as methyltrimethoxysilane, dimethyldimethoxysilane and trimethylmethoxysilane; methylethoxysilanes such as methyltriethoxysilane, dimethyldiethoxysilane and trimethylethoxysilane; methylacetoxysilanes such as methyltriacetoxysilane, dimethyldiacetoxysilane and trimethylacetoxysilane; vinylsilanes such as vinyltrichlorosilane, vinylmethyldichlorosilane, vinyldimethylchlorosilane, vinyltrimethoxysilane, vinylmethyldimethoxysilane, vinyldimethylmethoxysilane, vinyltriethoxysilane, vinylmethyldiethoxysilane and vinyldimethylethoxysilane.

Suitable disilazanes include for example, but are not limited to: hexamethyldisilazane, divinyltetramethyldisilazane and bis(3,3-trifluoropropyl)tetramethyldisilazane. Cyclosilazanes are also suitable, and include, for example, octamethylcyclotetrasilazane. It is noted that the aforementioned disilazanes and cyclosilazanes typically have the basic formula (I) and (II) described above. Thus, these disilazanes and cyclosilazanes can be used as either or both as hydrophobizing material for hydroponically modifying fumed silica particles and as a processing aid in forming the pre-dispersion mentioned supra.

Suitable fluorinated silanes include the fluorinated alkyl-, alkoxy-, aryl- and/or alkylaryl-silanes, and fully perfluorinated alkyl-, alkoxy-, aryl- and/or alkylaryl-silanes. Examples of fluoroalkyl silanes include, but are not limited to: those marketed by Degussa under the trade name of DYNASYLAN. An example of a suitable fluorinated alkoxy-silane is perfluorooctyl trimethoxysilane.

### Zinc Oxide:

A preferred embodiment of the present invention utilizes a micro fine transparent nanometer sized zinc oxide powder. Its homogeneous small particles and narrow particle size distribution provides for excellent transparency. It is non-migratory and has antibacterial properties.

Regular commercially available zinc oxides have specific surface areas below 10 m₂/gr, (typically 4-6 m₂/gr), resulting in high primary particle sizes which results in white particle in appearance. The mean particle diameter of the zinc oxide utilized in the present invention is about 35 nanometers and the majority of the particles range from about 20 to 35 nanometers. One source of the nanometer sized zinc oxide, (ZANO 20) is Umicore Zinc Chemicals in Belguim. One preferred embodiment utilizes zinc oxide particles having a specific surface area of minimum 20 m₂/gr, resulting in very fine loosely aggregated particles having a primary particle size below 60 nanometer providing a narrow particle size distribution allowing the zinc oxide to be used in transparent applications. Additional zinc oxide products available from Umicore Zinc Chemicals suitable for use in the present invention is sold under the trade name of ZANO LS and has a specific surface are of 20-30 m₂/gr and a primary particle size (calculated) of about 35-55 nanometers; and ZANO HS which has a specific surface are of 30-40 m₂/gr and a primary particle size (calculated) of about 25-35 nanometers. The homogeneous particle size distribution of the nanometer sized particle and its fine primary particle size result in good transparency. The nanometer sized zinc oxide particles are broad spectrum UV absorbers (UV-A and UV-B) which is not the case for micro fine TiO2 and organic UV absorbers. It also has anti-bacterial properties and is mildew resistant.

An alternate embodiment utilizes zinc oxide having an average particle size of 60 nanometers (calculated via SSA measurement) sold under the trade name of NANOGARD by Nanophase Technologies Corporation, in Romeoville, Ill. Although it is sold as a white powder, the nanometer sized particles in low concentrations utilized in the preferred embodiments of the instant invention appear transparent.

The zinc oxide in at least one preferred embodiment of the present invention is present in an effective amount of up to 1.0 percent by weight of the total composition. The more preferred embodiments of the invention utilizes an effective amount ranging from 0.001 to 1.0 percent by weight, and more preferably in a range of from to 0.005 to 0.6 percent by weight, and more preferably in a range of from between 0.01 to 0.4 percent by weight, and more preferably between 0.05 to 0.2 percent by weight based on the total weight of the composition.

Another preferred class of UV and abrasion resistant hydrophobic polymers are the perfluoro alkyl substituted acrylic polymers. This class of polymers has excellent hydrophobicity and good abrasion resistance.

### Hydrocarbon Wetting Agents

In order to disperse treated, hydrophobic silica or other hydrophobic particles into water, the hydrophobic particles must be wetted by a non-aqueous liquid such as ketone, glycol ethers, alcohols, aliphatic hydrocarbon solvents, polydimethylsiloxane, cyclic polydimethylsiloxane, aromatic hydrocarbon solvents, tetrahydrofuran, acetic acid, acetates, glycols. The hydrophobic particles are easier to disperse after wetting with one or more solvents, preferably acetone, alcohol, for instance isopropyl alcohol, and/or aliphatic hydrocarbons and/or other solvents to make it dispersible.

The hydrophobic particles are mixed with an amount of wetting agent to completely dampen the free flowing hydrophobic particles and may form a paste.

A non VOC material may be selected or a VOC exempt material may be selected to produce a non VOC hydrophobic particle dispersion in water. Surfactants may also be used to help wet the metal surface in order to form a uniform super hydrophobic coating. Surfactants can be nonionic, cationic or anionic in nature.

Light distillate wetting agents useful in the formulation are predominately aliphatic hydrocarbon solvents and other light distillates. For instance, hydrocarbons containing up to 100 percent aliphatic hydrocarbons are most preferable and hydrocarbons containing less than 1 percent aromatic content are deemed very desirable. Also useful are solvents typically containing from about 10 to 90 percent aliphatic hydrocarbons and from about 0 to 10 percent aromatic hydrocarbons. Solvents deemed suitable which contain less than 10% aromatic hydrocarbons include odorless mineral spirits, Stoddard solvent, and mixed alkanes that have a flash point of about 40° C. A light distillate sold under the trade name of CALUMET 420-460 (LVP100), can be utilized in the composition.

Light Distillate hydrocarbons containing up to 100 percent aliphatic hydrocarbons are most preferable and hydrocarbons containing less than 1 percent aromatic content are deemed very desirable. Also useful are solvents typically containing from about 10 to 90 percent aliphatic hydrocarbons and from about 0 to 10 percent aromatic hydrocarbons. Solvents deemed suitable which contain less than 10% aromatic hydrocarbons include odorless naphtha, mineral spirits, turpentine, kerosene, V.M.& P naphtha, Stoddard solvent, and mixed alkanes that have a flash point of about 40° C.

The present invention contains light distillate hydrocarbons in an effective amount of between 0.001 to 15 percent by weight, more preferably between 0.01 to 10 percent by weight, and more preferably 0.1 to 5 percent by weight based on the weight of the total composition.

For instance, about 3 wt % acetone was used to wet the hydrophobic particles used in Example 1.

### Surfactant

Surfactants may also be used to help wet the metal surface in order to form a uniform super hydrophobic coating. Surfactants can be nonionic, cationic or anionic in nature.

One preferred surfactant sold under the tradename of SURFYNOL 61 which is dimethyl hexynol in an amount of 0.01 to 2 wt %. The surfactant helps in forming a film and wetting the surface to be coated with the water dispersion.

Other suitable surfactants include nonionic surfactants having an HLB value of from between 9-13, ethoxylated nonylphenols, ethoxylated octylphenols, branched ethoxylated alcohols, linear ethoxylated alcohols, and silicone surfactants. These surfactants are sold under the trade names of Tomah, Triton, Surfonic, Igepal, Alfonic, Rhodia, etc.

### Propellant:

A preferred method of application is by aerosol spraying. Applicable propellants are carbon dioxide, a hydrocarbon (for example mixtures of propane isobutane), a fluorocarbon, difloroethane, nitrogen, or compressed air. One preferred hydrocarbon is A 55.

In one preferred embodiment, a pressurized liquid propellant is utilized as the carrier to apply the composition without any further addition of carriers or solvents.

A commercial liquid hydrocarbon propellant can be selected which is compatible with the preferred composition. Propellants may be selected from blends of propane/isobutane/butane with the most preferred propellant as A 55 or A 70 for use with particular compositions. A commercial liquid hydrocarbon propellant is selected from the group consisting of A-31, A-46, A-55, A-70, or A-108, and/or propane/isobutane/butane blends, with A-55 and A-70 being the most preferred propellant for use with particular compositions. The composition may contain up to 30 weight percent of the propellant, and more preferably from 5 to 20 weight percent of the propellant. Moreover the composition can be formulated as a premix liquid concentrate and mixed with a desired amount of propellant. For example, a typical formula may contain about 88 percent by weight of a premix liquid concentrate and about 12 percent by weight of a selected propellant. As an alternative, other propellants such as pressurized air, N₂, or CO2 may also be used.

The composition may contain up to 99.9 weight percent of propellant, and more preferably from 0 to 90 weight percent of propellant and more preferably from about 80 to 90 wt % propellant.

### Dyes

As an option, a dye can be added to the composition to provide a desirable color or tint. Of course, it is contemplated that an effective amount could comprise more or less dye or tint up to 1% of the total weight of the composition.

Other colorants suitable for use in the instant composition include metallized azos such as barium or calcium salts, naphthol, pyrazalones, rhodamines, quinacridones, phthalocyanines, phthalocyanines, pigments including the magnesium salts, lead chromes and silicochromates, zinc chromes, barium chromate, strontium chromate, titanium nickel yellow, liminites, haematites, magnetites, micaceous oxides of iron, iron ferreites and Prussian blue.

### Preservatives:

A biocide, such as DANTOGARD (DMDM Hydantoin) or TROYSAN 395 can be optionally used as a preservative in the product. The biocide is not a necessary component to provide a functional composition for use on surfaces; however, depending upon the optional ingredients added to the formulation, the preservative may increase the useful shelf life to the product. The biocide preservative would be added in an effective amount to preserve the composition product and ranges from 0.001 to 2.0 percent by weight, and more preferably in a range of from 0.05 to 1.0 percent by weight, and more preferably in a range of from between 0.1 and 0.5 percent by weight based on the total weight of the composition. Other preservatives such as polymethoxybicyclic oxazolidine, DANTOGARD, or SURCIDE P may also be useful in the present invention.

### Application:

The coating composition of the instant invention was applied to a substrate surface by spraying, dipping, brushing, or spin-coating the surface being treated.

Stability was determined by observing that the super hydrophobic effect has not diminished and by examining the film under the microscope before and after exposure.

In one preferred embodiment, the hydrophobic fumed silica nanoparticles are blended into the solvent until completely dispersed and then the zinc oxide nanoparticles are mixed until a good dispersion is obtained at ambient temperature. The mixture is then placed in an aerosol container with an effective amount of a propellant to spray the composition onto the surface to be treated. If used, a fragrance, colorant, or preservative is added prior to adding the composition to its container.

A preferred method of application is by spraying the particle dispersion as an aerosol. Suitable propellants are for example hydrocarbon of from 1 to 15 carbon atoms, such as n-propane, n-butane, isobutane, n-pentane, isopentane, and mixtures thereof, dimethyl ether and blend thereof as well as individual or mixtures of choloro-, chlorofluoro-, and/or difluoro or fluorohydrocarbons and/or hydrochlorofluorocarbons (HCFCs). Also suitable as propellant as compressed gas such as carbon dioxide, compressed air, nitrogen, and possibly dense or supercitical fluids may also be used, ether alone or combination, and alternatively and combination with other propellant types.

If propellant is used it will generally be in an amount from about 10 wt % to about 100 wt % of the aerosol formulation. Normally, the amount of a particular propellant should provide an internal pressure of from about 40 to 100 p.s.i.g. at 70° F. The suspended treated silica generally will be in an amount from about 0.1 wt % to about 10 wt % of the aerosol formulation.

Wetting the hydrophobic particle with acetone and/or aliphatic hydrocarbons and/or other VOC complaint solvent makes it easier to apply and disperse making it sprayable. The solvent wetting agent may also be selected from the groups consisting of an alcohol, a hydrocarbon, mineral spirits, or water.

One preferred method of treatment of a surface with the composition of the present invention is generally applied as an aerosol in a manner so as to deposit fine droplets of the composition comprising the colloidally dispersed hydrophobically modified fumed silica particles in a water based carrier as a continuous coating upon a receptive surface such that the droplets completely cover the surface to effectively merge to form a thin continuous transparent film coating. The composition is applied as a substantially clear hydrophobic self-cleaning coating to a metal, plastic, glass, cloth, ceramic, clay, fiber, concrete, brick, rock, cinder block, paper, film, or wood surface. After application of a uniform coating to the treated surface, the composition cures by drying and evaporation of the water carrier and solvent wetting agent forming a coating or film at ambient temperature within 5 to 10 minutes of the application. The film dries by evaporation of the water based carrier and solvent wetting agent leaving a deposited film of particles in the form of silica or other selected hydrophobic particle agglomerates than is essentially transparent. The uniform and transparent film is detachable and renewable. It exhibits dirt-repellency and water repellency owing to high water contact angles sufficient to effect beading water incident on the surface so that the deposited film exhibits provides soil and water repellency. Moreover, the treated surface is self-cleaning.

The transparency and haze of the coating produced was measured by a HAZE GARD PLUS instrument for a composition having a concentration of the silica in diluent of 200 nm.

| | | | | | |
|---|---|---|---|---|---|
| % Treated Fumed Silica | 0.3 | 0.5 | 0.8 | 1.0 | 4.0 |
| Transmittance (%) | 93.9 | 93.8 | 94.0 | 93.7 | 93.0 |
| Haze (%) | 2.35 | 3.26 | 3.26 | 3.22 | 4.36 |

### EXAMPLES

The following examples provide formulations of compositions in accordance with the present invention and provide examples of the range of ingredient percentages by weight providing an effective amount of the particular ingredients deemed necessary to obtain the desired results in a single application. The examples are provided for exemplary purposes to facilitate understanding of the invention and should not be construed to limit the invention to the examples.

### Example 1

### No Binder

A typical formulation consisting essentially of 0.3 wt % solid of fumed silica (Aerosil R 8200 from Degussa) wetted by an ordorless mineral spirit solvent wetting agent in an amount of about 3 wt % together with a surfactant sold under the tradename of SURFYNOL 61 which is dimethyl hexynol in an amount of 1 wt %. After wetting the fumed silica with the mineral spirits and surfactant, it was dispersed in water by ultrasonic sheering. The final formulation is coated on a painted metal panel using aerosol propellent comprising from 80 to 90 wt % of A-70. The super hydrophobic property was retained for more than 4 weeks when exposed to UV light, rain etc. before showing any degradation.

### Example 2

### No Binder

Another preferred embodiment formulation consisting essentially of 0.2 wt % solid of fumed silica (CAB-O-SIL TS-720 from Cabot) that is wetted with acetone (3 wt %) and Tomadol 23.5 (0.05 wt %) forming a paste. This paste was then diluted with water (to 100%). The dispersion was then coated on a painted metal surface. The film generated by this formulation showed excellent super hydrophobic property (contact angle>165 degree). The super hydrophobic property was maintained for more than 4 weeks under UV light, rain etc, before showing any signs of degradation.

### Example 3

### No Binder

Another preferred embodiment comprises a formulation consisting essentially of 0.05 wt % of a treated solid nanoparticle of ZnO and Degussa LE-3, a surfactant such as SURFYNOL 61 at 0.05 wt % and Surfonic N-60 at 0.05 wt %, wetted with an acetone solvent wetting agent comprising about 3 wt % and the remaining water. The coating composition was coated on an unpainted metal surface by using a trigger sprayer. The film generated by this formulation showed excellent hydrophobic property (contact angle>165 degree). The super hydrophobic property was maintained for more than 4 weeks under UV light, rain, etc before exhibiting signs of degradation.

### Example 4

### With Binder

Another preferred embodiment comprises a formulation consisting essentially of 0.3 wt % solid of fumed silica (Aerosil R 202 from Degussa) and a surfactant such as Igepal DM-530 wetted with an acetone solvent wetting agent in an amount of about 3 wt % and diluted with water. The formulation was similar to the formulation in Example 1 except that the instant example contains 0.1 wt % of binder (Beeswax) as a binder. The coating composition was applied to a painted metal surface using an air operated spray gun. The super hydrophobic property (contact angle of 165 degree) was maintained for more than 4 weeks under UV light, rain, etc. prior to showing any signs of degradation.

The foregoing detailed description is given primarily for clearness of understanding and no unnecessary limitations are to be understood therefrom, for modification will become obvious to those skilled in the art upon reading this disclosure and may be made upon departing from the spirit of the invention and scope of the appended claims. Accordingly, this invention is not intended to be limited by the specific exemplifications presented herein above. Rather, what is intended to be covered is within the spirit and scope of the appended claims.

We claim:

1. A water based hydrophobic self cleaning coating composition comprising:
a wetting agent solvent selected from the group consisting of a ketone, an aliphatic hydrocarbon, an alcohol, a glycol ether, a glycol, a polyglycol,
nanoparticles selected from the class consisting of treated fumed silica, treated hydrophobic titania, zinc oxides;
a surfactant consisting of cationic, nonionic or anionic surfactants;
a water carrier; and
wherein an effective amount of said treated fumed silica is wetted with said wetting agent solvent and said surfactant dispersed in said water carrier results in a coated surface providing a contact angle of at least 165 degrees as compared to water having a contact angle of from 65 to 80 degrees on a noncoated surface and imparts a degree of hydrophobicity to a surface so that the surface will have a tilt angle of sliding of less than 2 degrees as compared to water on a noncoated surface having a tilt angle of sliding of 90 degrees or higher.

2. The water based hydrophobic coating composition of claim 1, further comprising a propellant selected from the group consisting of carbon dioxide, a hydrocarbon (propane, butane, isobutane), CO2, nitrogen, fluorocarbon, difloroethane, and compressed air;

3. The hydrophobic coating composition of claim 1, wherein said UV stable hydrophobic polymer comprises a perfluoro alkyl substituted acrylic polymer.

4. The hydrophobic coating composition of claim 1, wherein said UV stable hydrophobic polymer comprises a trimethylsilyl end capped siloxane

5. The hydrophobic coating composition of claim 1, wherein no wetting agent solvent is used to make the composition.

6. The hydrophobic coating composition of claim 1, wherein no surfactant is used to make the composition.
